(19) United States
(12) Patent Application Publication
(10) Pub. No.: US 2012/0074455 A1
(43) Pub. Date: Mar. 29, 2012

(54) LED PACKAGE STRUCTURE

(75) Inventors: YING-CHIEH LU, Chu-Nan (TW); CHIH-MING LAI, Chu-Nan (TW)

(73) Assignee: FOXSEMICON INTEGRATED TECHNOLOGY, INC., Chu-Nan (TW)

(21) Appl. No.: 13/300,630

(22) Filed: Nov. 20, 2011

Related U.S. Application Data
(66) Substitute for application No. 12/891,818, filed on Sep. 28, 2010, now abandoned.

(51) Int. Cl. H01L 33/52

(52) U.S. Cl. 257/99; 257/E33.059

(57) ABSTRACT

An LED package structure includes a heat conductive plate defining a concave groove therein, an LED die received in the concave groove, an eutectic layer sandwiched between the heat conductive plate and the substrate, a transparent encapsulant encapsulating the LED die on the heat conductive plate. The heat conductive plate forms an electrode circuit layer on the heat conductive plate around the concave groove. The LED die forms electrodes electrically connected with the electrode circuit layer. An electrically insulating heat conduction grease filled around the substrate and the eutectic layer.

### BACKGROUND

1. Technical Field

The present disclosure relates to a light emitting diode (LED) package structure.

2. Description of Related Art

Presently, LEDs are preferred for use in non-emissive display devices than CCFLs (cold cathode fluorescent lamp) due to their high brightness, long lifespan, and wide color range.

A related LED package structure includes an LED die adhered on a printed circuit board (PCB) via a conductive adhesive such as Ag paste, and then the printed circuit board is thermally attached to a metal plate. However, there are many interface layers including a substrate of the LED, electrodes, the conductive adhesive, and the PCB, between the LED die and the metal plate, so that a large thermal resistance against heat to be transferred exists between the LED die and the metal plate.

What is needed, therefore, is a new LED package structure which can overcome the limitations described.

### BRIEF DESCRIPTION OF THE DRAWINGS

FIG. 1 is a cross-sectional view of an LED package structure according to a first embodiment of the present disclosure.

FIG. 2 is a cross-sectional view of an LED package structure according to a second embodiment of the present disclosure.

FIG. 3 is a cross-sectional view of an LED package structure according to a third embodiment of the present disclosure.

### DETAILED DESCRIPTION

Embodiments of the disclosure will now be described in detail with reference to the accompanying drawings.

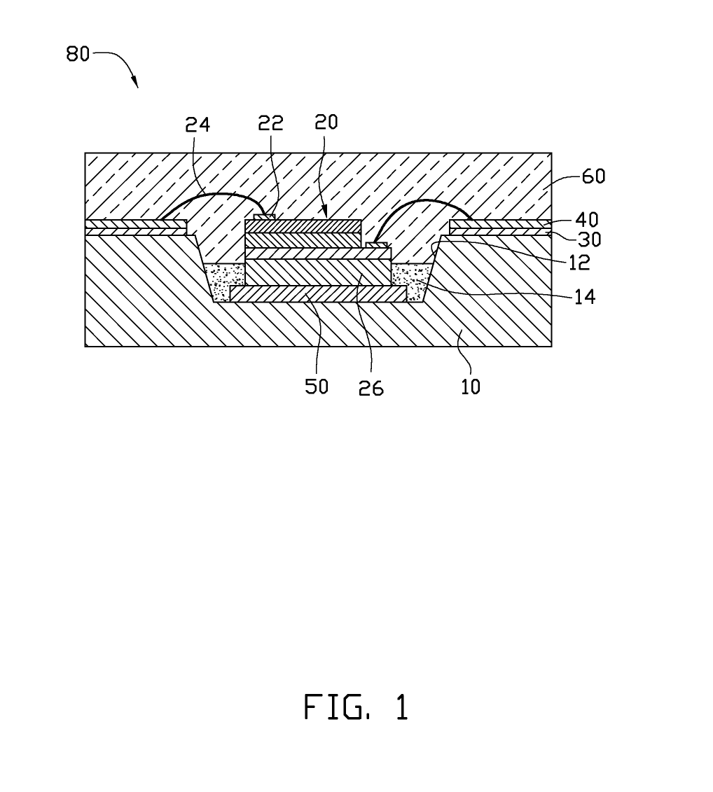

Referring to FIG. 1, an LED package structure 80 in accordance with a first embodiment of the disclosure is illustrated. The LED package structure 80 includes a heat conductive plate 10, an LED die 20, and a transparent encapsulant 60 encapsulating the LED die 20 on the heat conductive plate 10.

The heat conductive plate 10 has a thermal conductivity larger than 20 W/mK, and can be made of metallic material, such as copper, copper-alloy, aluminum or aluminum-alloy. Alternatively, the heat conductive plate 10 can be of non-metal material, such as silicon. The heat conductive plate 10 is flat and has a coefficient of thermal expansion substantially equal to that of a substrate 26 of the LED die 20. The heat conductive plate 10 defines a concave groove 12 for receiving the LED die 20.

The heat conductive plate 10 forms an electrically insulating layer 30 thereon and an electrode circuit layer 40 on the electrically insulating layer 30. The electrically insulating layer 30 can be a dielectric layer, a plastic macromolecule layer or a solid flat layer. The dielectric layer can be made of SiO₂, SiₓN_{y}, SiₓO_{y}N_{z}, spin-on glass (SOG), Al₂O₃, AlN or AlₓO_{y}N_{z}. The plastic macromolecule layer can be made of PMMA, polycarbonate (PC), polyethylene terephthalate (PET), epoxy resin or silicone. The solid flat layer can be made of fiberglass or polyimide (PI).

When a Si plate is selected as the heat conductive plate 10, the electrically insulating layer 30 can be a dielectric layer formed on the heat conductive plate 10 by one of the following methods: 1. oxidating method, i.e., directly oxidizing the Si plate to form a SiO₂ layer on the Si plate; 2. nitridizing method, i.e., blowing nitrogen on the Si plate at a high temperature to form a SiₓN_{y} layer on the Si plate; 3. combining the above two methods to form a SiₓO_{y}N_{z} layer; 4. spin coating method, i.e., spreading the Si plate with spin-on glass (SOG) and then heating the Si plate at a suitable temperature to evenly form a SiO₂ layer on the Si plate.

When an Al plate is selected as the heat conductive plate 10, the electrically insulating layer 30 can be a dielectric layer formed on the heat conductive plate 10 by one of the following methods: 1. oxidating method, i.e., directly oxidizing the Al plate to form an Al₂O₃ layer on the Al plate; 2. nitridizing method, i.e., blowing nitrogen on the Al plate at a high temperature to form an AlN layer on the Al plate; 3. combining the above two methods to form a compound layer (AlₓO_{y}N_{z}) containing elements of Al, O and N on the Al plate. In the processes of above methods for forming the electrically insulating layer 30, dissociated air can be blown onto the Al plate to form plasma, thereby increasing speed and density of forming the oxide or the nitride.

The electrode circuit layer 40 can be of at least one selected from Ni, Au, Sn, Be, Al, In, Ti, Ta, Ag, Cu or an alloy thereof. Alternatively, the electrode circuit layer 40 can be of a transparent conducting oxide (TCO), such as Indium Tin Oxides (ITO), Ga-doped ZnO (GZO) or Al-doped ZnO (AZO). The electrode circuit layer 40 can be formed on the electrically insulating layer 30 by physical deposition method, such as sputter, Physical Vapor Deposition (PVD) or e-beam evaporation deposition. The electrode circuit layer 40 can also be formed by chemical deposition method, such as chemical vapor deposition (CVD), electroplating chemical deposition or screen printing.

The LED die 20 can be a phosphide represented by general formula AlₓIn_{y}Ga_{(1-x-y)}P, here 0≦x≦1, 0≦y≦1 and x+y≦1; or an arsenide represented by general formula AlₓIn_{y}Ga_{(1-x-y)}As, here 0≦x≦1, 0≦y≦1 and x+y≦1. The LED die 20 can also be made of a semiconductor material capable of emitting light of a wavelength which can excite fluorescent material, for example, the LED die 20 can be of an oxide such as ZnO, or a nitride, such as GaN. The LED die 20 is preferably made of a nitride semiconductor material represented by general formula InₓAl_{y}Ga_{(1-x-y)}N, here 0≦x≦1, 0≦y≦1 and x+y≦1, which can emit light of short wavelengths ranged from ultraviolet light to blue light to excite fluorescent material. The LED die 20 includes the substrate 26 which can be made of an intrinsic semiconductor or an unintentionally doped semiconductor and a light emitting unit (not labeled) formed on the substrate 26. Particularly, the substrate 26 can be of a semiconductor material, such as spinel, SiC, Si, ZnO, GaN, GaAs, GaP or AlN. The substrate 26 can also be of a material with good thermal conductivity but poor electrical conductivity, such as diamond. The carrier concentration of the substrate 26 is preferably 5×10⁶ cm⁻³ or lower, and more preferably 2×10⁶ cm⁻³ or lower, so that the electric current can be electrically insulated from flowing through the substrate 26.

The LED die 20 is received in the groove 12 of the heat conductive plate 10. A eutectic layer 50 is formed between the heat conductive plate 10 and the LED die 20. The eutectic layer 50 is formed by two metal layer (not shown) respectively connecting with the heat conductive plate 10 and the substrate 26 of the LED die 20 joined together by eutectic bonding. The eutectic layer 50 contains at least one selected from Au, Sn, In, Al, Ag, Bi, Be or an alloy thereof.

An electrically insulating heat conduction grease 14 is then filled in a gap of the groove 12 between the heat conductive plate 10 and the LED die 20. In this embodiment, the electrically insulating heat conduction grease 14 is filled around the substrate 26 and the eutectic layer 50, thereby thermally connecting the substrate 26, the eutectic layer 50 and the heat conductive plate 10 together. Electrodes 22 are formed on the LED die 20 and electrically connected with the electrode circuit layer 40 by metal wires 24. The metal wires 24 can be made of Au, Sn, In, Al, Ag, Bi, Be or an alloy thereof.

The encapsulant 60 can be made of silicone, epoxy resin or PMMA (polymethyl methacrylate). The encapsulant 60 can be hemispherical, dome-shaped or quadrate. To convert wavelength of light generated from the LED die 20, a fluorescent material such as sulfides, aluminates, oxides, silicates or nitrides, can be filled and scattered in the encapsulant 60.

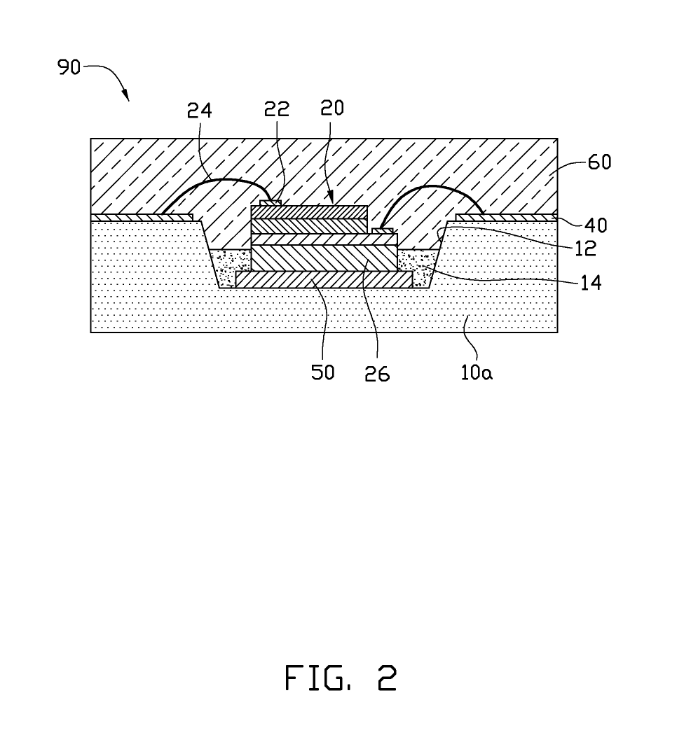

Referring to FIG. 2, an LED package structure 90 in accordance with a second embodiment of the disclosure is illustrated. The LED package structure 90 is substantially identical to the LED package structure 80 in accordance with the first embodiment of the present disclosure, differing only a heat conductive plate 10a employs electrically insulating material and the electrode circuit layers 40 are directly formed on the heat conductive plate 10a without the any electrically insulating layer therebetween.

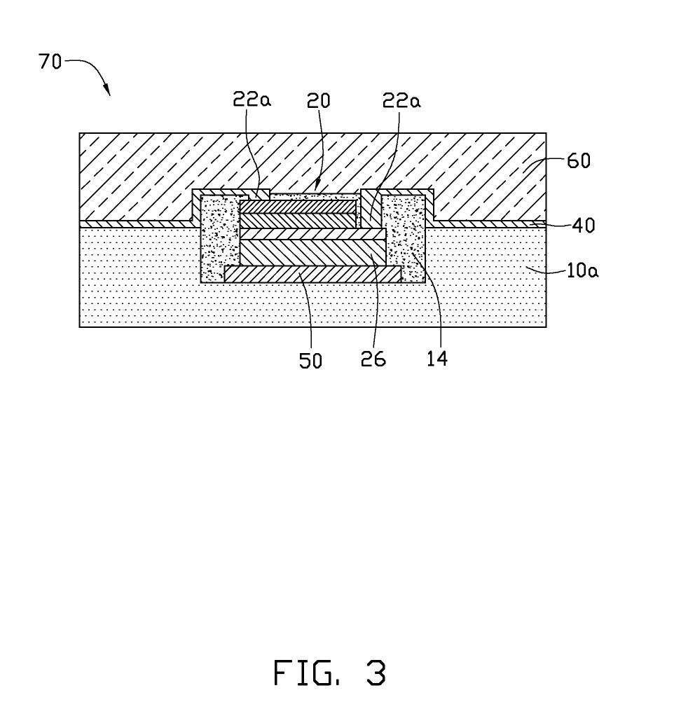

Referring to FIG. 3, an LED package structure 70 in accordance with a third embodiment of the disclosure is illustrated. Different from the LED package structure 90 of the second embodiment, the LED package structure 70 includes electrodes 22a respectively connecting the LED die 20 and the electrode circuit layers 40. The electrodes 22a are integrally formed with the electrode circuit layers 40 by lithography, in place of the metal wires 24 of the second embodiment. The heat conduction grease 14 is filled around the LED die 20 and thermally connecting the LED die 20 with the heat conductive plate 10a. In this embodiment, the electrodes 22a of the LED die 20 have substantially the same heights thereby facilitating the manufacture of the LED package structure 70. The electrodes 22a and the heat conduction grease 14 can be made of transparent material.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) package structure, comprising:
a heat conductive plate defining a concave groove therein, the heat conductive plate forming an electrode circuit layer on the heat conductive plate around the concave groove;
an LED die received in the concave groove of the heat conductive plate, the LED die having a substrate and electrically connecting with the electrode circuit layer;
an eutectic layer sandwiched between the heat conductive plate and the substrate; and
a transparent encapsulant encapsulating the LED die on the heat conductive plate.

2. The LED package structure of claim 1, further comprising an electrically insulating, heat conduction grease filled around the substrate and the eutectic layer, thereby thermally connecting the substrate, the eutectic layer and the heat conductive plate together.

3. The LED package structure of claim 1, further comprising an electrically insulating layer between the heat conductive plate and the electrode circuit layer, and two metal wires electrically connecting the LED die and the electrode circuit layer.

4. The LED package structure of claim 3, wherein the heat conductive plate is made of copper, copper-alloy, aluminum or aluminum-alloy.

5. The LED package structure of claim 3, wherein the heat conductive plate is Si plate, and the electrically insulating layer is made of SiO₂, SiₓN_{y}, or SiₓO_{y}N_{z}.

6. The LED package structure of claim 3, wherein the heat conductive plate is Al plate, and the electrically insulating layer is made of AlₓO_{y}N_{z}.

7. The LED package structure of claim 1, wherein the heat conductive plate is made of electrically insulating material and the electrode circuit layer is directly formed on the heat conductive plate.

8. The LED package structure of claim 1, wherein the heat conductive plate is a ceramic material having electrically insulating property selected from AlₓO_{y}, AlN or ZrO₂.

9. The LED package structure of claim 1, further comprising an electrically insulating, heat conduction grease filled around the LED die, and two electrodes respectively connecting the LED die and the electrode circuit layers, the electrodes being integrally formed with the electrode circuit layer.

10. The LED package structure of claim 9, wherein the electrodes of the LED package structure have substantially same heights.

11. The LED package structure of claim 1, wherein the heat conductive plate has a thermal conductivity larger than 20 W/mK.

12. The LED package structure of claim 1, wherein the heat conductive plate has a coefficient of thermal expansion substantially equal to that of the substrate of the LED die.
